(19) United States
(12) Patent Application Publication
(10) Pub. No.: US 2023/0395742 A1
(43) Pub. Date: Dec. 7, 2023

(54) OPTICAL SENSOR HAVING 2D-3D HETEROJUNCTION STRUCTURE AND MANUFACTURING METHOD THEREOF

(71) Applicant: AJOU UNIVERSITY INDUSTRY-ACADEMIC COOPERATION FOUNDATION, Suwon-si (KR)

(72) Inventors: Junseok HEO, Suwon-si (KR); Aujin HWANG, Suwon-si (KR); Youngseo PARK, Busan (KR)

(73) Assignee: AJOU UNIVERSITY INDUSTRY-ACADEMIC COOPERATION FOUNDATION, Suwon-si (KR)

(21) Appl. No.: 18/032,720

(22) PCT Filed: Feb. 2, 2021
(86) PCT No.: PCT/KR2021/001377

§ 371 Date: Apr. 19, 2023

(30) Foreign Application Priority Data
Nov. 27, 2020 (KR) 10-2020-0161924

(51) Int. Cl. H01L 31/109; H01L 31/18

(52) U.S. Cl. CPC H01L 31/109; H01L 31/18

(57) ABSTRACT

Disclosed is an optical sensor including a three-dimensional (3D) material layer doped with first conductivity type impurities at a first doping concentration, and a two-dimensional material layer doped with second conductivity type impurities at a second doping concentration and arranged in contact with the three-dimensional material layer to form a type II band alignment with the three-dimensional material layer.

### TECHNICAL FIELD

The present disclosure relates to an optical sensor and a manufacturing method thereof, and more particularly, to an optical sensor having a heterojunction structure of a two-dimensional material and a three-dimensional material, and a manufacturing method thereof.

### BACKGROUND ART

An optical sensor is a device that converts and detects light energy such as visible light that can be detected by the human eye, ultraviolet, and infrared light into an electrical signal, and is based on the principle of operation of a photoelectric effect. The application fields of these optical sensors are mainly classified according to a light wavelength region to which each optical sensor is sensitive. Optical sensors in a visible light region are mainly applied to image sensors of mobile devices and digital cameras for obtaining images, optical sensors in an infrared region are applied to bio, bio-signal and security fields, and optical sensors in an ultraviolet region are mainly applied to fire and environmental safety fields.

Recently, as the need for optical sensors with new concepts and various functions increases, related research is also continuously increasing. In particular, due to the advent of drone, robot, and self-driving vehicle technology, not only the need for various sensor technologies has increased, but also the need for optical sensor technology that applies different light wavelength regions or complementary effects is emerging for the stable operation of unmanned vehicles during day and night.

To this end, research on optical sensors based on new materials ranging from organic semiconductors, inorganic compound semiconductors, and low-dimensional semiconductor materials, which are being actively researched recently, is being conducted. In addition, in terms of device structure as well as new materials, research and development are being conducted on ways to utilize various structures such as Schottky junction structures, heterojunction structures, and phototransistors in addition to p-n junction structures.

However, in the case of an optical sensor for detecting various wavelengths, since it is implemented in a way of integrating and configuring a plurality of individual sensors according to the use of visible light and infrared light, application to a high-resolution image sensor is impossible due to image distortion, and light detection efficiency is reduced due to an increase in the area of a light receiving area, a driving circuit area, and a wiring circuit area, and there is a limit to weight reduction and miniaturization.

### DESCRIPTION OF EMBODIMENTS

### Technical Problem

The present disclosure provides an optical sensor capable of selecting a sensitive wavelength band and detecting a broadband wavelength through control of an operating voltage, and capable of being lightweight and miniaturized, and a manufacturing method thereof.

The inventive concept of the disclosure is not limited to the above objectives, but other objectives not described herein may be clearly understood by those of ordinary skilled in the art from descriptions below.

### Solution to Problem

According to an aspect of the disclosure, there is provided an optical sensor, the optical sensor includes: a three-dimensional (3D) material layer doped with first conductivity type impurities at a first doping concentration; and a two-dimensional (2D) material layer doped with second conductivity type impurities at a second doping concentration and arranged in contact with the 3D material layer to form a type II band alignment with the 3D material layer.

According to an exemplary embodiment, the first conductivity type impurities may be p-type impurities, and the second conductivity type impurities may be n-type impurities.

According to an exemplary embodiment, the first doping concentration may be greater than the second doping concentration.

According to an exemplary embodiment, a band gap of the 3D material layer may be less than a band gap of the 2D material layer.

According to an exemplary embodiment, the 3D material layer may include at least one of a group IV semiconductor material, a group IV-IV compound semiconductor material, and a group III-V compound semiconductor material, and
the 2D material layer may include at least one of a metal chalcogenide-based material, a carbon-containing material, and an oxide semiconductor material.

According to an exemplary embodiment, due to the formation of the type II band alignment, the 2D material layer and the 3D material layer may respond to light in an infrared region when a zero bias is applied and may respond to at least one of light in the infrared region and light in a visible light region when a certain reverse bias is applied.

According to an exemplary embodiment, the optical sensor may further include an insulating layer disposed on the 3D material layer and partially exposing an upper surface of the 3D material layer to define an area where a portion of the upper surface of the 3D material layer and the 2D material layer come into contact with each other; a first contact configured to cover a portion of an upper surface of the insulating layer and a portion of an upper surface of the 2D material layer; and a second contact configured to cover at least a portion of a lower surface of the 3D material layer.

According to another aspect of the disclosure, there is provided a method of manufacturing an optical sensor, the method includes: forming an insulating layer on a 3D material layer doped with first conductivity type impurities at a first doping concentration; etching a portion of the insulating layer to partially expose an upper surface of the 3D material layer; and forming a 2D material layer doped with second conductivity type impurities at a second doping concentration to cover a portion of the exposed upper surface of the 3D material layer.

According to an exemplary embodiment, the forming of the 2D material layer may include: forming a preliminary 2D material layer on a portion of the exposed upper surface of the 3D material layer; and doping the preliminary 2D material layer with the second conductivity type impurities to have the second doping concentration to form the 2D material layer.

According to an exemplary embodiment, the forming of the 2D material layer may include: forming the 2D material layer doped with the second conductivity type impurities at the second doping concentration on a carrier substrate; and transferring the 2D material layer from the growth substrate to the insulating layer to cover a portion of the exposed upper surface of the 3D material layer.

According to an exemplary embodiment, the first conductivity type impurities may be p-type impurities, and the second conductivity type impurities may be n-type impurities.

According to an exemplary embodiment, the first doping concentration may be greater than the second doping concentration.

According to an exemplary embodiment, a band gap of the 3D material layer may be less than a band gap of the 2D material layer.

According to an exemplary embodiment, the 3D material layer may include at least one of a group IV semiconductor material, a group IV-IV compound semiconductor material, and a group III-V compound semiconductor material, and the 2D material layer may include at least one of a metal chalcogenide-based material, a carbon-containing material, and an oxide semiconductor material.

According to an exemplary embodiment, the method may further include: forming a first contact to cover a portion of an upper surface of the insulating layer and a portion of an upper surface of the 2D material layer; and forming a second contact to cover at least a portion of a lower surface of the 3D material layer.

### Advantageous Effects of Disclosure

According to embodiments of the inventive concept, an optical sensor is a heterojunction of a two-dimensional material and a three-dimensional material, but forms a type II band alignment in which a barrier is formed for a valence band of the two-dimensional material in an equilibrium state, thereby selectively separating visible light and infrared light or detecting them simultaneously with simple operating voltage control.

Accordingly, it is possible to implement a high-performance optical sensor capable of selecting a sensitive wavelength band without loss of a light-receiving area and detecting a wide range of wavelengths, as well as reducing manufacturing cost, miniaturization, and weight reduction.

Effects obtainable by embodiments of the inventive concept are not limited to the effects described above, and other effects not described herein may be clearly understood by one of ordinary skill in the art to which the present disclosure belongs from the following description.

### BRIEF DESCRIPTION OF DRAWINGS

A brief description of each drawing is provided to more fully understand drawings recited in the present disclosure.

FIG. 1 is a schematic cross-sectional view of an optical sensor according to an exemplary embodiment of the present disclosure.

FIG. 2 is a band diagram showing a band alignment of a three-dimensional material layer and a two-dimensional material layer forming a heterojunction in the optical sensor of FIG. 1.

FIGS. 3 and 4 are band diagrams for explaining the principle of operation of the optical sensor of FIG. 1.

FIGS. 5 and 6 are views for describing light response characteristics of an optical sensor according to an exemplary embodiment of the present disclosure.

FIG. 7 is a view for explaining a method of manufacturing an optical sensor according to an exemplary embodiment of the present disclosure.

### MODE OF DISCLOSURE

Embodiments according to the inventive concept are provided to more completely explain the inventive concept to one of ordinary skill in the art, and the following embodiments may be modified in various other forms and the scope of the inventive concept is not limited to the following embodiments. Rather, these embodiments are provided so that the present disclosure will be thorough and complete, and will fully convey the scope of the inventive concept to one of ordinary skill in the art.

It will be understood that, although the terms first, second, etc. may be used herein to describe various members, regions, layers, sections, and/or components, these members, regions, layers, sections, and/or components should not be limited by these terms. These terms do not denote any order, quantity, or importance, but rather are only used to distinguish one component, region, layer, and/or section from another component, region, layer, and/or section. Thus, a first member, component, region, layer, or section discussed below could be termed a second member, component, region, layer, or section without departing from the teachings of embodiments. For example, as long as within the scope of this disclosure, a first component may be named as a second component, and a second component may be named as a first component.

Unless otherwise defined, all terms (including technical and scientific terms) used herein have the same meaning as commonly understood by one of ordinary skill in the art to which the inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

When a certain embodiment may be implemented differently, a specific process order may be performed differently from the described order. For example, two consecutively described processes may be performed substantially at the same time or performed in an order opposite to the described order.

In the drawings, variations from the illustrated shapes may be expected because of, for example, manufacturing techniques and/or tolerances. Thus, embodiments of the inventive concept should not be construed as being limited to the particular shapes of regions illustrated herein but may include deviations in shapes that result, for example, from manufacturing processes. Like reference numerals in the drawings denote like elements, and thus their overlapped explanations are omitted.

As used herein, the term “and/or” includes any and all combinations of one or more of the associated listed items.

Hereinafter, a vertical photodiode having a p-n heterojunction is exemplified as an optical sensor according to an exemplary embodiment of the present disclosure, but the present disclosure is not limited thereto. An optical sensor according to the inventive concept may be implemented with other types of devices such as a horizontal photodiode, a vertical or horizontal phototransistor, and the like.

Hereinafter, embodiments of the inventive concept will be described in detail with reference to the accompanying drawings.

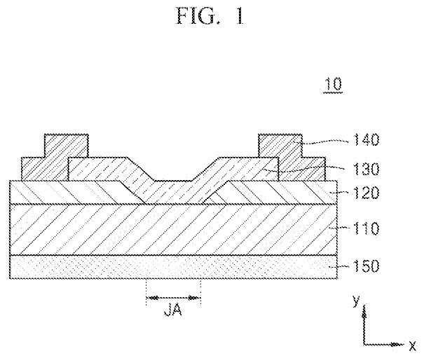

FIG. 1 is a schematic cross-sectional view of an optical sensor according to an exemplary embodiment of the present disclosure.

Referring to FIG. 1, an optical sensor 10 may include a three-dimensional (3D) material layer 110, an insulating layer 120, a two-dimensional (2D) material layer 130, a first contact 140, and a second contact 150.

The 3D material layer 110 may generate a photocurrent by responding to light in a certain wavelength range, more specifically, by absorbing light in a certain wavelength range, and may include a semiconductor material having a 3D crystal structure.

The 3D material layer 110 may include a material having an energy band gap of about 1.2 eV or less (hereinafter referred to as a band gap) and responding to light in an infrared region.

For example, the 3D material layer 110 may include group IV semiconductor materials such as Ge, group IV-IV compound semiconductor materials such as GeSn, and group III-V compound semiconductor materials such as InGaAs and InP.

The 3D material layer 110 may be formed to a thickness of several to several tens of nm. However, the thickness of the 3D material layer 110 is not limited to the range of several to several tens of nm, and may vary within a range that satisfies light absorption requirements of a desired wavelength band and carrier mobility.

The 3D material layer 110 may have p-type conductivity. In this case, the 3D material layer 110 may be doped with p-type impurities at a first doping concentration, but is not limited thereto. The 3D material layer 110 may have a conductivity type opposite to that of the 2D material layer 130.

An insulating layer 120 may be on the 3D material layer 110.

The insulating layer 120 may be a layer for separating the 3D material layer 110 and the 2D material layer 130 to be described later, and defining a heterojunction area of the 3D material layer 110 and the 2D material layer 130.

For example, the insulating layer 120 may cover an upper surface of the 3D material layer 110 and may have a recess area exposing a portion of the upper surface of the 3D material layer 110. The recess area may define a junction area JA in which a portion of a lower surface of the 2D material layer 130 is joined to a portion of the upper surface of the 3D material layer 110 exposed in the recess area. The recess area may have a circular cross-sectional shape perpendicular to a y-direction, but is not limited thereto. The shape of a cross-section perpendicular to the y-direction of the recess area may be implemented in various shapes without limitation, such as a circular shape, an elliptical shape, a polygonal shape, and a shape with irregular curvature. An inner wall of the recess area may be inclined such that an area of a cross section perpendicular to the y-direction (or a width in an x-direction) increases in the y-direction, but is not limited thereto. The inner wall of the recess area may be parallel to the y-direction. As such, the recess area may be implemented to have various structures.

The insulating layer 120 may include an insulating material such as a metal oxide such as Al2O3, an oxide, a nitride, or an oxynitride.

The 2D material layer 130 may be on the insulating layer 120.

The 2D material layer 130 may cover the entire recess area to form a heterojunction with a portion of the upper surface of the 3D material layer 110 exposed to the recess area of the insulating layer 120. In addition, the 2D material layer 130 may cover a portion of an upper surface of the insulating layer 120 adjacent to the recess area.

The 2D material layer 130 may generate a photocurrent by responding to light in a certain wavelength range, more specifically, by absorbing light in a certain wavelength range, and may include a semiconductor material having a 2D crystal structure.

The 2D material layer 130 may have a single-layer or half-layer structure, but is not limited thereto. The 2D material layer 130 may have a stacked structure in which a certain number of single layers and/or half-layers are repeatedly stacked.

The 2D material layer 130 may include a material having a bandgap energy of about 1.2 to 1.8 eV and responding to light in a visible light region.

For example, the 2D material layer 130 may include at least one of a metal chalcogenide-based material, a carbon-containing material, and an oxide semiconductor material.

The metal chalcogenide-based material may be a transition metal dichalcogenide (TMDC) material including a transition metal and a chalcogen material. The transition metal may be at least one of Mo, W, Nb, V, Ta, Ti, Zr, Hf, Tc, and Re, and the chalcogen material may be at least one of S, Se, and Te.

The metal chalcogenide-based material may include a metal chalcogenide material including a non-transition metal, and the non-transition metal may include, for example, Ga, In, Sn, Ge, or Pb.

The carbon-containing material may be a carbon-containing material such as graphene, and when the 2D material layer 130 includes graphene, at least one graphene may be included.

The oxide semiconductor material may be a material including a Ga oxide semiconductor, a Zn oxide semiconductor, or an In oxide semiconductor.

The 2D material layer 130 may be formed to a thickness of several to several tens of nm. However, the thickness of the 2D material layer 130 is not limited to the range of several to several tens of nm, and may vary within a range that satisfies light absorption requirements of a desired wavelength band and carrier mobility.

The 2D material layer 130 may have n-type conductivity. In this case, the 2D material layer 130 may be doped with n-type impurities at a second doping concentration, but is not limited thereto. The 2D material layer 130 may have a conductivity type opposite to that of the 3D material layer 110.

Meanwhile, the second doping concentration of the 2D material layer 130 may be less than the first doping concentration of the 3D material layer 110. Due to the difference in doping level between the 3D material layer 110 and the 2D material layer 130, at the time of heterojunction of the 3D material layer 110 and the 2D material layer 130, their bands form a type II band alignment (or a staggered band alignment). Thus, the optical sensor 10 may selectively separate or simultaneously sense visible light and infrared light according to control of an operating voltage.

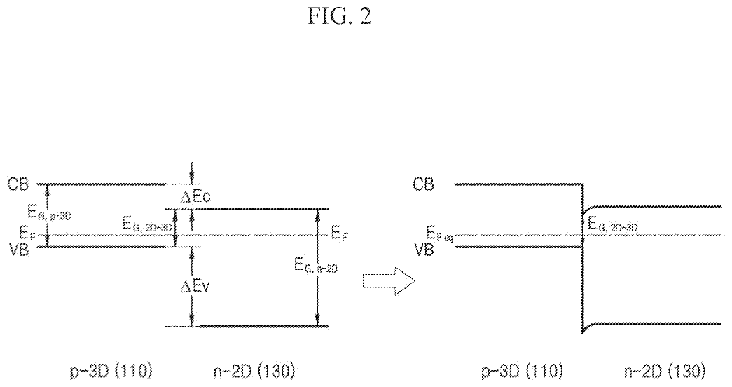

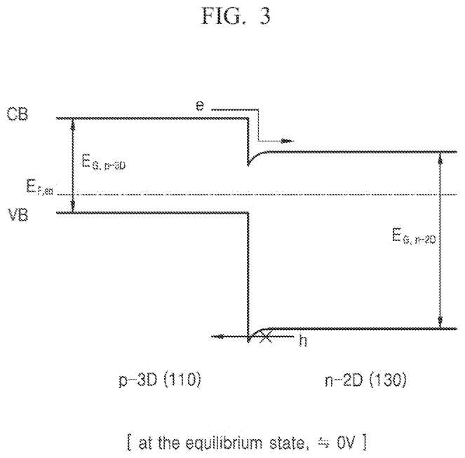

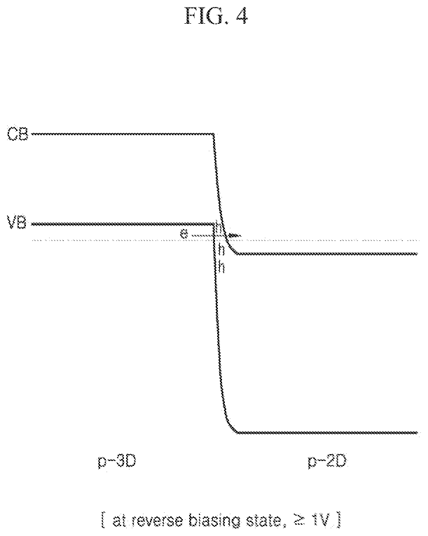

FIG. 2 is a band diagram showing a band alignment of the 3D material layer 110 and the 2D material layer 130 forming a heterojunction in the optical sensor 10 of FIG. 1, and FIGS. 3 and 4 are band diagrams for explaining the principle of operation of the optical sensor 10. FIGS. 2 to 4 illustrate band diagrams at the time of heterojunction of the 3D material layer 110 having a relatively high doping level of p-type impurities and the 2D material layer 130 having a relatively low doping level of n-type impurities.

First, referring to FIG. 2, the 3D material layer 110 having a relatively small band gap (EG, p-3D) and the 2D material layer 130 having a relatively large band gap (EG, p-3D) are joined. At this time, as an energy difference (ΔEc) between conduction bands CB and an energy difference (ΔEv) between valence bands VB of each layer have the same sign, for example, positive (+), a type II band alignment is formed. In addition, when carriers of each layer reach equilibrium, due to the relatively low doping level, a conduction band CB and a valence band VB of the 2D material layer 130 are bent downward toward a junction interface, and a Fermi level of each layer is flattened. As a result, the size of an energy gap (EG, 2D-3D) between the 3D material layer 110 and the 2D material layer 130 is reduced compared to before a heterojunction is formed, and a barrier is formed to restrict movement of carriers, that is, holes, on the valence band VB of the 2D material layer 130.

As shown in FIG. 3, when light is irradiated in an equilibrium state, that is, a zero bias state, photocurrent is generated while electrons generated by light in an infrared region in the 3D material layer 110 move toward the 2D material layer 130. However, holes generated by light in a visible light region in the 2D material layer 130 do not move toward the 3D material layer 110, so no photocurrent is generated. As a result, in the optical sensor 10, only a current by light in the infrared region is detected.

As shown in FIG. 4, when light is irradiated with a reverse bias of 1 V or higher applied, as the conduction band CB and the valence band VB of the 2D material layer 130 go down, unlike the equilibrium state, the conduction band CB and the valence band VB bend upward toward the junction interface. As the magnitude of the reverse bias gradually increases, the thin 2D material layer 130 is fully depleted. At this time, there is no current change in the optical sensor 10 because a dark current is greater than a light current due to electrons generated by light in the infrared region in the 3D material layer 110. On the other hand, holes generated by light in the visible light region in the fully depleted 2D material layer 130 are trapped at the junction interface, and electrons in the valence band VB of the 3D material layer 110 move to the conduction band CB of the 2D material layer 130 due to the trap (i.e., trap-assisted tunneling). As a result, as the quantum efficiency of visible light exceeds 100%, a photocurrent equal to or greater than the dark current is generated, and the optical sensor 10 detects only a current by the light in the visible light region.

Meanwhile, when the thickness of the 2D material layer 130 is sufficient so that the 2D material layer 130 is not completely depleted in a state where a reverse bias is applied, effects due to the depletion of the 2D material layer 130 described above are mitigated, and accordingly, the optical sensor 10 may detect both photocurrents by visible light and infrared light.

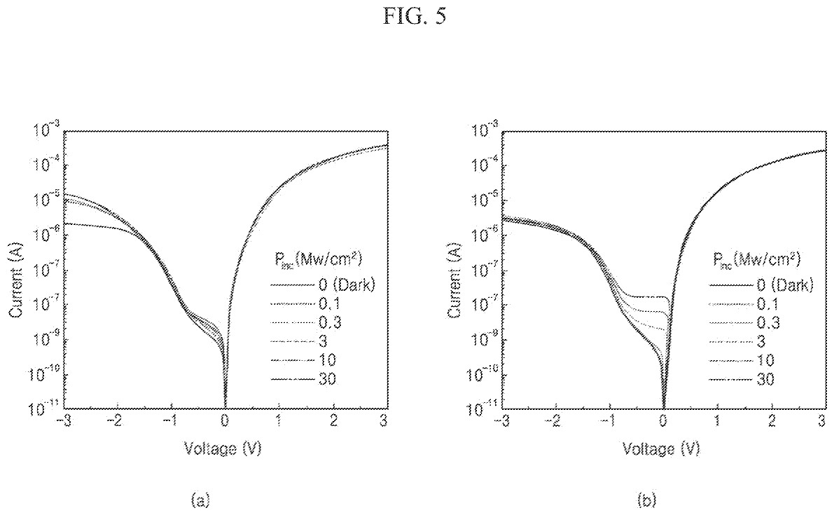

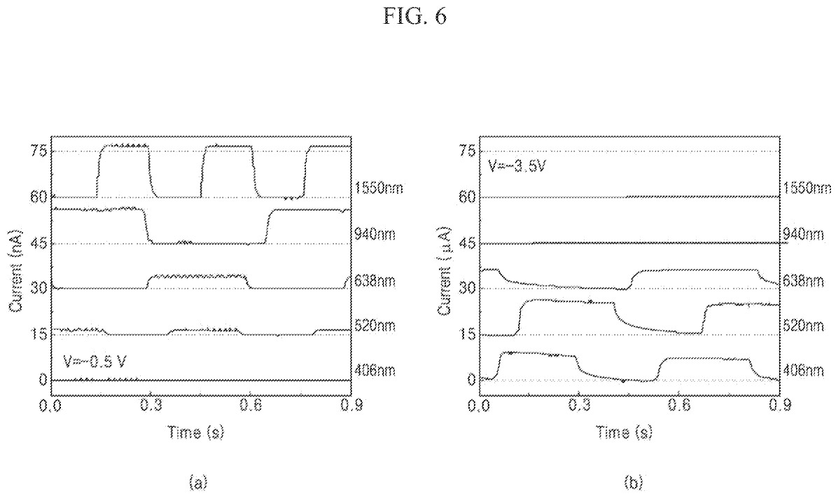

FIGS. 5 and 6 are views for describing light response characteristics of an optical sensor according to an exemplary embodiment of the present disclosure. FIGS. 5 and 6 show, for example, current and voltage characteristics when light of a specific wavelength is irradiated to an optical sensor including a p-Ge and n-MoS2 heterojunction.

FIG. 5 (a) is a graph showing current-voltage characteristics of an optical sensor when 406 nm light is irradiated, FIG. 5 (b) is a graph showing current-voltage characteristics of an optical sensor when 1550 nm light is irradiated, FIG. 6 (a) is a graph showing a current change of an optical sensor according to a wavelength when −0.5V is applied, and FIG. 6 (b) is a graph showing a current change of an optical sensor according to a wavelength when −3.5V is applied.

As shown in FIGS. 5 and 6, in the optical sensor including a heterojunction of p-Ge and n-MoS2, a photocurrent is generated for infrared light at around 0 V, but no photocurrent is generated for visible light. On the other hand, when a reverse bias of 1 V or more is applied, in the above-described optical sensor, there is no change in current for infrared light, but a change in current for visible light.

As such, the optical sensor 10 according to the inventive concept may selectively or simultaneously detect visible light and infrared light according to control of an operating voltage while the 3D material layer 110 and the 2D material layer 130 forming a heterojunction form a type II band alignment.

Due to this, the optical sensor 10 may detect a wide range of wavelengths as well as a selective wavelength band without loss of a light-receiving area, enabling high performance, and manufacturing cost of the optical sensor 10 or a device to which the optical sensor 10 is applied may be reduced, as well as miniaturization and weight reduction.

Referring back to FIG. 1, the first contact 140 may be on the insulating layer 120 to cover a portion of an upper surface of the insulating layer 120 and a side end portion of the 2D material layer 130. In addition, the second contact 150 may be on a lower surface of the 3D material layer 110.

The first and second contacts 140 and 150 may include a conductive material, such as metal or conductive oxide. For example, the first and second contacts 140 and 150 may include metals such as Ti, Pt, Ru, Au, Ag, Mo, Al, W, Ni, Ta, or Cu, an alloy, or a conductive oxide such as IZO (InZnO) or AZO (AlZnO). In addition, each of the first and second contacts 140 and 150 may be formed as a single layer or multiple layers.

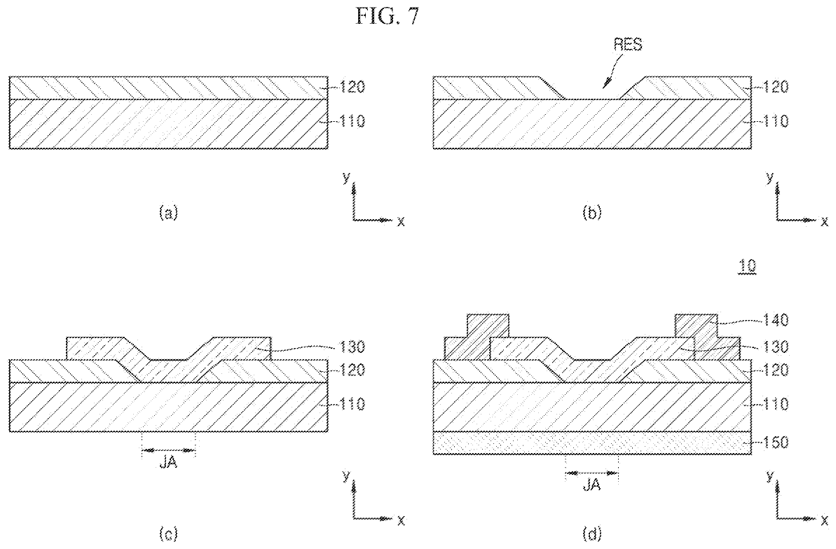

FIG. 7 is a view for explaining a method of manufacturing an optical sensor according to an exemplary embodiment of the present disclosure. FIG. 7 illustrates a method of manufacturing the optical sensor 10 shown in FIG. 1. In the description of FIG. 7, the same reference numerals as in FIG. 1 denote the same elements, and descriptions thereof will not be given herein, and only the differences from FIG. 1 will be mainly described.

Referring to FIG. 7 (a), the insulating layer 120 is formed on the 3D material layer 110.

The 3D material layer 110 may be a substrate including a 3D material doped with first conductivity type impurities at a first doping concentration. However, the present disclosure is not limited thereto, and the 3D material layer 110 may be formed by doping a substrate including an intrinsic 3D material with first conductivity type impurities at a first doping concentration through an ion implantation process or the like.

The insulating layer 120 may be formed by an atomic layer deposition (ALD) process, a chemical vapor deposition (CVD) process, or a physical vapor deposition (PVD) process.

Referring to FIG. 7 (b), a portion of the insulating layer 120 is etched to define a recess area RES exposing a portion of an upper surface of the 3D material layer 110.

For example, a mask layer is formed on the insulating layer 120 and then patterned, a portion of the insulating layer 120 is etched using the patterned mask layer as an etch mask, and the remaining mask layer is removed to define the recess area RES exposing a portion of the upper surface of the 3D material layer 110.

Referring to FIG. 7 (c), the 2D material layer 130 is formed to cover a portion of the upper surface of the 3D material layer 110 exposed in the recess area RES.

The 2D material layer 130 may include a 2D material doped with second conductivity type impurities at a second doping concentration. The second doping concentration may be less than the first doping concentration.

In the recess area RES, the 2D material layer 130 comes into contact with the exposed 3D material layer 110 to form a heterojunction, and the 2D material layer 130 and the exposed 3D material layer 110 form a type II band alignment.

In some embodiments, a preliminary 2D material layer may be directly formed on the 3D material layer 110 and the insulating layer 120 by metal organic chemical vapor deposition (MOCVD), molecular beam epitaxy (MBE), chemical beam epitaxy (CBE), hydride vapor phase epitaxy (HYPE), ALD process, etc. Next, the 2D material layer 130 may be formed by doping the preliminary 2D material layer with the second conductivity type impurities at the second doping concentration and then patterning the preliminary 2D material layer.

In another embodiment, a preliminary 2D material layer may be formed on a separate carrier substrate (or a growth substrate) using the MOCVD, MBE, CBE, HYPE, ALD process, etc., or through a mechanical or chemical exfoliation process. Next, the preliminary 2D material layer may be doped with the second conductivity type impurities at the second doping concentration by an ion implantation process or the like to form the 2D material layer 130, and the formed 2D material layer 130 may be transferred to the insulating layer 120 to cover the 3D material layer.

Referring to FIG. 7 (d), the first contact 140 is formed to partially cover a portion of an upper surface of the insulating layer 120 and a portion of an upper surface of the 2D material layer 130, and the second contact 150 is formed to cover at least a portion of a lower surface of the 3D material layer 110.

While the present disclosure has been particularly shown and described with reference to embodiments thereof, it should not be construed as being limited to the descriptions set forth herein.

In addition, it will be apparent to one of ordinary skill in the art that various changes and modifications are possible within a range that does not deviate from the basic principles of the present disclosure.

What is claimed is:

1. An optical sensor comprising:
a three-dimensional (3D) material layer doped with first conductivity type impurities at a first doping concentration; and
a two-dimensional (2D) material layer doped with second conductivity type impurities at a second doping concentration and arranged in contact with the 3D material layer to form a type II band alignment with the 3D material layer.

2. The optical sensor of claim 1, wherein the first conductivity type impurities are p-type impurities, and
the second conductivity type impurities are n-type impurities.

3. The optical sensor of claim 1, wherein the first doping concentration is greater than the second doping concentration.

4. The optical sensor of claim 1, wherein a band gap of the 3D material layer is less than a band gap of the 2D material layer.

5. The optical sensor of claim 1, wherein the 3D material layer includes at least one of a group IV semiconductor material, a group IV-IV compound semiconductor material, and a group III-V compound semiconductor material, and
the 2D material layer includes at least one of a metal chalcogenide-based material, a carbon-containing material, and an oxide semiconductor material.

6. The optical sensor of claim 1, wherein, due to the formation of the type II band alignment, the 2D material layer and the 3D material layer respond to light in an infrared region when a zero bias is applied and respond to at least one of light in the infrared region and light in a visible light region when a certain reverse bias is applied.

7. The optical sensor of claim 1, further comprising:
an insulating layer disposed on the 3D material layer and partially exposing an upper surface of the 3D material layer to define an area where a portion of the upper surface of the 3D material layer and the 2D material layer come into contact with each other;
a first contact configured to cover a portion of an upper surface of the insulating layer and a portion of an upper surface of the 2D material layer; and
a second contact configured to cover at least a portion of a lower surface of the 3D material layer.

8. A method of manufacturing an optical sensor, the method comprising:
forming an insulating layer on a 3D material layer doped with first conductivity type impurities at a first doping concentration;
etching a portion of the insulating layer to partially expose an upper surface of the 3D material layer; and
forming a 2D material layer doped with second conductivity type impurities at a second doping concentration to cover a portion of the exposed upper surface of the 3D material layer.

9. The method of claim 8, wherein the forming of the 2D material layer comprises:
forming a preliminary 2D material layer on a portion of the exposed upper surface of the 3D material layer; and
doping the preliminary 2D material layer with the second conductivity type impurities to have the second doping concentration to form the 2D material layer.

10. The method of claim 8, wherein the forming of the 2D material layer comprises:
forming the 2D material layer doped with the second conductivity type impurities at the second doping concentration on a carrier substrate; and
transferring the 2D material layer from the growth substrate to the insulating layer to cover a portion of the exposed upper surface of the 3D material layer.

11. The method of claim 8, wherein the first conductivity type impurities are p-type impurities, and
the second conductivity type impurities are n-type impurities.

12. The method of claim 8, wherein the first doping concentration is greater than the second doping concentration.

13. The method of claim 8, wherein a band gap of the 3D material layer is less than a band gap of the 2D material layer.

14. The method of claim 8, wherein the 3D material layer includes at least one of a group IV semiconductor material, a group IV-IV compound semiconductor material, and a group III-V compound semiconductor material, and
the 2D material layer includes at least one of a metal chalcogenide-based material, a carbon-containing material, and an oxide semiconductor material.

15. The method of claim 8, further comprising:
forming a first contact to cover a portion of an upper surface of the insulating layer and a portion of an upper surface of the 2D material layer; and
forming a second contact to cover at least a portion of a lower surface of the 3D material layer.
